(19) United States
(12) Patent Application Publication
(10) Pub. No.: US 2015/0228916 A1
(43) Pub. Date: Aug. 13, 2015

(54) BOTTOM-UP ULTRA-THIN FUNCTIONAL OPTOELECTRONIC FILMS AND DEVICES

(71) Applicant: MASSACHUSETTS INSTITUTE OF TECHNOLOGY, Cambridge, MA (US)

(72) Inventors: Vladimir BULOVIC, Lexington, MA (US); Joel JEAN, Cambridge, MA (US); Annie I-Jen WANG, Cambridge, MA (US)

(21) Appl. No.: 14/608,504

(22) Filed: Jan. 29, 2015

Related U.S. Application Data
(60) Provisional application No. 61/932,854, filed on Jan. 29, 2014.

(51) Int. Cl. H01L 51/00; H01L 51/44

(52) U.S. Cl. CPC H01L 51/0097; H01L 51/448; H01L 51/003; H01L 51/0035; H01L 51/0056; H01L 51/0072; H01L 51/0081; H01L 51/0059

(57) ABSTRACT

The embodiments disclosed herein are directed to optoelectronic devices based, on ultra-thin, lightweight and in-situ deposited parylene substrates, as well as methods of manufacture. Using a bottom-up approach, a readily releasable parylene thin film can be used for fabricating thin film electronic and optoelectronic systems on the thin and light substrates having thicknesses in the nanometer to low micron range. The disclosed method enables the integration of forming a parylene substrate with, the fabrication of a complete photovoltaic device under a fully contained, controlled environment.

This application claims priority to U.S. Provisional Application No. 61/932,854, which was filed Jan. 29, 2014 and which is fully incorporated herein by reference.

### BACKGROUND

1. Field

The present invention relates generally to organic thin films for use in energy-producing organic photovoltaic devices. In particular, the present invention is directed to ultra-thin, lightweight clean and flexible parylene substrates and encapsulation layers, their methods of manufacture, and photovoltaic devices derived therefrom.

2. Description of the Related Art

Solar photovoltaics (PV) are among the few low-carbon energy technologies with the scalability to satisfy global electricity demand. Today's leading crystalline silicon (c-Si) and commercial thin-film PV modules are low-cost, efficient, and reliable, but also rigid and heavy (up to 30 kg for a 300 W module). Such a restricted module form factor contributes to high balance-of-system costs, which dominate PV system cost and binder low-cost deployment.

Low weight-specific power is one key limitation of crystalline silicon (c-Si) wafer-based solar ceil technology dominating the solar photovoltaic (PV) market today. The specific power of a PV cell or module is its peak power output per unit weight (W/g). Heavy-solar panels may be difficult and expensive to transport and install, adding to the total, cost of solar PV systems for grid-connected power generation. Furthermore, many alternative applications for solar ceils require high specific power to be feasible or marketable. For example, total payload weight is often an important consideration for space and military technologies. Ultra-lightweight solar cells may enable solar-powered portable consumer electronics. A lightweight PV module could facilitate deployment in remote areas and in countries with unreliable power grids. Such customer demands drive the research and development of thin-film solar cells, i.e., PV's based on thin and lightweight semiconducting films. Thin films (21 100 nm to 10 μm thickness) of light absorbing semiconductors (e.g., cadmium telluride) and organic small molecules (e.g., tetraphenyldibenzoperiflanthene (DBP), buckminsterfullerene) weigh very little compared to conventional silicon wafers (typically about 1.60 μm thickness) and can be extremely flexible. However, such advantages are lost when heavy glass sheets are used as substrate and encapsulation layers, as in today's commercial thin-film PV modules. The most common substrate material today is glass, which presents a flat smooth, robust surface for cell processing and protects sensitive organic and hybrid materials from exposure to oxygen and water vapor. However, a rigid glass sheet dominates cell weight and thickness, eliminating potential advantages, such as flexibility and high specific power. A typical glass substrate or cover is 3-4 mm thick and weighs ˜8 kg/m², dwarfing the active layer and constraining specific power for a given cell efficiency.

To overcome these limitations, researchers have investigated the use of lightweight thermoplastic, cellulosic and textile substrates. Ideal lightweight substrates provide both mechanical support and environmental protection. The choice of substrate is critical for realizing key advantages of emerging thin-film PV, such as scalable roll-to-roll processability of large-area solar cells, intrinsic flexibility, high power-to-weight ratios (or weight-specific power), low material usage, and stretchability.

Active matrix sensor arrays and light-emitting devices on ˜1-2 μm thick PET and PEN substrates have recently been shown to have relatively high robustness and performance. Other studies have targeted substrates made of cellulosic materials, common papers, polyimide, stainless-steel foil, plastic and other materials to expand the solar PV market to portable and wearable electronics, medical applications, and future optoelectronic devices. Many of these films are conducive to scalable roll-to-roll processing and are already produced commercially in high volumes. However, surface roughness or particle contamination on many such substrates can be comparable to the thickness of the active layers.

Thin PV substrates made of conventional PET, PEN, polyimides and stainless steel foil may encounter some challenges intrinsic to their manufacture. These substrates are formed using top-down processes, such as calendaring, drawing, and blown- or cast-film extrusion, which start with a bulk material feedstock and manipulate it to create the desired structure. Though widely used in traditional manufacturing, top-down techniques offer limited control over the thickness and uniformity of extremely thin (sub-micron) substrates and films, due to the limited precision of mechanical elements, such as molds and rollers. Furthermore, top-down methods require manufacturing equipment distinct from bottom-up methods used in electronic and optoelectronic device fabrication. Additional packaging, transportation, cleaning, and surface preparation steps are thus required prior to device fabrication. Further, intrinsic and extrinsic surface defects are often unavoidable in such conventional films. Such defects range in size (laterally and vertically) from tens of nanometers to tens of microns and present a major shorting risk for large-area thin-film optoelectronic devices like displays and solar cells, for example, surface defects in PET and PEN films range in size from below 200 nm to about 10 μm. As a result, an additional planarizing layer or thicker buffer layers may be required to avoid defects, shorts, or other non-idealities. Such layers add processing complexity. Furthermore, thin free-standing commercial PET and PEN substrates are expensive on both a per-weight and per-area basis and must be handled with extreme care.

Accordingly, there is a need for alternative substrate materials that avoid these shortcomings while providing advantageous characteristics of being thin, lightweight, flexible, durable, transparent, laminable, manufacturable at low cost and resistant to both UV exposure and water penetration.

### SUMMARY

In one aspect, the disclosure relates to a photovoltaic device including a substrate layer comprising parylene, and one or more active photovoltaic layers disposed over the substrate layer. The substrate layer can have a thickness of between about 100 nm to about 10 μm and a thickness tolerance of about ±10 nm. The active photovoltaic layers include an anode layer, a donor layer, an acceptor layer, and a cathode layer. The photovoltaic device can have a weight-specific power of at least about 1 W/g and a total thickness of the photovoltaic device can be less than about 1.5 μm.

The active photovoltaic layers can also include a first interlayer disposed between the anode layer and the donor layer; and a second interlayer disposed between the acceptor layer and the cathode layer. The photovoltaic device can also include one or more encapsulation layers disposed over the active photovoltaic layers.

In another aspect, the disclosure relates to a method to form a multilayer photovoltaic device, which includes depositing parylene over one of a rigid or a semi-rigid carrier surface to form a substrate layer, wherein the substrate layer has a thickness of between about 100 nm to about 10 μm and a thickness tolerance of about ±10 nm; forming one or more active photovoltaic layers over the substrate layer; and separating the substrate from the rigid or the semi-rigid carrier surface. Parylene can be deposited on the rigid or semi-rigid carrier surface by vapor deposition. The substrate layer can have a thickness of between about 250 nm to about 5 μm and a thickness tolerance of about ±10 nm. In one embodiment, the method can also include depositing parylene over the one or more active photovoltaic layers to form an encapsulation layer. All fabrication steps can be performed in continuous succession in a contained, controlled environment, such as under continuous vacuum or in inert atmosphere. The multilayer photovoltaic device maintains structural integrity and does not rip or tear when the substrate layer is separated from the rigid or the semi-rigid carrier surface.

The active photovoltaic layers can be formed by forming an anode layer over the substrate layer; forming a donor layer over the anode layer; forming an acceptor layer over the donor layer; and forming a cathode layer over the acceptor layer. The active photovoltaic layers can also be formed by forming a cathode layer over the substrate layer; forming an acceptor layer over the cathode layer; forming a donor layer over the acceptor layer; and forming an anode layer over the donor layer. In some embodiments, the method further includes forming a first interlayer between the anode layer and the donor layer; and forming a second interlayer between the acceptor layer and the cathode layer. The methods herein can form a photovoltaic device having a thickness of less than about 1.5 μm.

### BRIEF DESCRIPTION OF DRAWINGS

These and other embodiments of the invention will be discussed with reference to the following non-limiting and exemplary illustrations, in which like elements are numbered similarly, and where;

FIG. 1 shows various configurations of organic photovoltaic devices on parylene substrate;

FIG. 2 shows transparency and roughness of vapor-deposited parylene and alternative-flexible substrates, (a) Optical transmission spectra of parylene-C, PET, and PEN films with varying thicknesses over a wavelength range of 300 nm to 1000 nm. (b) AFM images of parylene-C on glass, PET, and PEN. (c) UV transmittance of parylene-C, quartz, and borosilicate glass from 200 nm to 400 nm;

FIG. 3 shows a roll-to-roll manufacturing process for fully vapor-deposited thin-film solar cells on parylene;

FIG. 4 shows a process for enhancing parylene substrates with functional coatings;

FIG. 5 shows an example of an electric field intensity profile in organic solar cells.

FIG. 6 shows: (a) a structure of an exemplary small-molecule organic photovoltaic device (OPV) on a parylene substrate; (b) a nominal energy baud diagram for a DBP-, C₆₀- and BCP-based organic photovoltaic device; (c) a photograph of a completed OPV on parylene; and (d) a cross-sectional view of a fully encapsulated OPV;

FIG. 7 shows photos of various parylene-C thin films of various thicknesses that are released from glass carrier wafers;

FIG. 8 shows a performance comparison of small-molecule organic solar cells on parylene-C and on glass substrates;

FIG. 9 shows the effect of substrate and active layers (including electrodes) on power-to-weight performance of current PV technologies;

FIG. 10 shows the power absorption coefficient for active layers (DBP and C₆₀);

FIG. 11 shows modeled electric field intensity map in OPV on glass and on parylene;

FIG. 12 shows modeled light absorption by layer in OPV on glass and on parylene; and

FIG. 13 shows the index of retraction (n) and extinction coefficient (k) of various OPV materials.

### DETAILED DESCRIPTION

Described herein is the use of parylene-based thin films as ultra thin transparent

substrates for optoelectronic devices. Using a bottom-up approach, a releasable parylene thin film can be used to enable the fabrication of thin film electronic and optoelectronic systems on the thinnest and lightest substrates yet demonstrated—in some cases thinner than the total active device thickness (for example, several hundred nanometers). Using in situ vapor-deposited parylene films, a complete multiplayer device can be fabricated without breaking vacuum, thus maintaining an ultra-clean environment and pristine substrate without extra cleaning steps. Parylene films can be deposited at room temperature directly onto conventional substrates (e.g., paper or plastic) as a planarizing buffer layer making a variety of surfaces appear chemically identical for subsequent device fabrication. One advantage of this approach is enabling the deployment of inexpensive disposable solar cells on paper and other common substrates. With its insulating and barrier properties, parylene can further serve as an encapsulant and interposer to isolate individual stacked devices both electrically and mechanically, allowing the development of complex stratified systems advantageously using a single commercially available polymer. The many chemical variants of parylene allows for customization of film properties for a variety of applications. Despite their micron or sub-micron thicknesses, parylene films remain intact upon removal from a backing surface: mechanical robustness and favorable surface properties enable dry-release from a carrier substrate without the need for soluble release layers or solvents.

Optoelectronic devices of the present invention include a parylene substrate and an active photovoltaic region having an anode and a cathode. Such optoelectronic devices can contain various layers or junction types disposed between the anode and cathode including, for example: i) a bilayer heterojunction having an electron donor layer and an electron acceptor layer, ii) a bulk heterojunction having a blend of admixed electron donor and electron acceptor, or iii) a graded heterojunction of admixed electron donor and election acceptor having a gradual gradient.

In some embodiments, the active photovoltaic region includes a bilayer heterojunction having a donor and an acceptor. In other embodiments, the active photovoltaic region can further include one or more interlayers (anode buffer layer) disposed between the anode and donor. In yet other embodiments, the active photovoltaic region can also include one or more interlayers (cathode buffer layer) disposed between the cathode and acceptor. In other embodiments, the active photovoltaic region can include one or more anode buffer layers and one or more cathode buffer layers.

Optoelectronic devices of the present invention can be made ultra-thin while providing power conversion efficiencies and device yields comparable to currently available glass-based devices. Optoelectronic devices can have overall thicknesses of between about 200 nm to about 20 μm or thicker, for example, between about 200 μm to about 10 μm, between about 200 nm to about 5 μm, between about 200 nm to about 3 μm, between about 200 nm to about 2 μm, between about 200 nm to about 1.5 μm, between about 200 nm to about 1.4 μm, between about 300 nm to about 10 μm, between about 300 nm to about 5 μm, between about 300 nm to about 3 μm, between about 300 nm. to about 1.5 μm, between about 400 nm to about 10 μm, between about 400 nm to about 5 μm, between about 400 nm to about 3 μm, between about 400 nm to about 2 μm, between about 400 nm to about 1.5 μm, between about 500 nm to about 5 μm, between about 500 nm to about 1.5 μm and between about 600 nm to about 1.5 μm, and between about 750 μm to about 1.5 μm. In some embodiments, optoelectronic devices can be as thin as less than about 500 nm, less than about 600 nm, less than about 1 μm, less than about 1.5 μm and less than about 5 μm. Optoelectronic devices can exhibit a weight-specific power of at least 0.01 W/g, at least 0.1 W/g, at least 1 W/g, at least 5 W/g and about 10 W/g or more. For example, weight-specific power can be between about 0.01 W/g to about 10 W/g, between about 0.01 W/g to about 8 W/g, between about 0.01 W/g to about 6 W/g, between about 0.01 W/g to about 4 W/g, between about 0.01 W/g to about 2 W/g, between about 0.01 W/g to about 1 W/g, between about 0.01 W/G to about 0.1 W/g, between about 0.1 W/g to about 10 W/g, between about 0.1 W/g to about 8 W/g, between about 0.1 W/g to about 6 W/g, between about 0.1 W/g to about 5 W/g, between about 0.1 W/g to about 4 W/g, between about 0.1 W/g to about 2 W/g, between about 0.1 W/g to about 1 W/g, between about 0.1 W/g to about 0.5 W/g, between about 1 W/g to about 10 W/g, between about 1 W/g to about 8 W/g, between about 1 W/g to about 6 W/g, between about 1 W/g to about 5 W/g, between about 1 W/g to about 4 W/g, between about 1 W/g to about 2 W/g, between about 2 W/g to about 8 W/g, between about 2 W/g to about 6 W/g, between about 4 W/g to about 8 W/g, and between about 5 W/g to about 7 W/g.

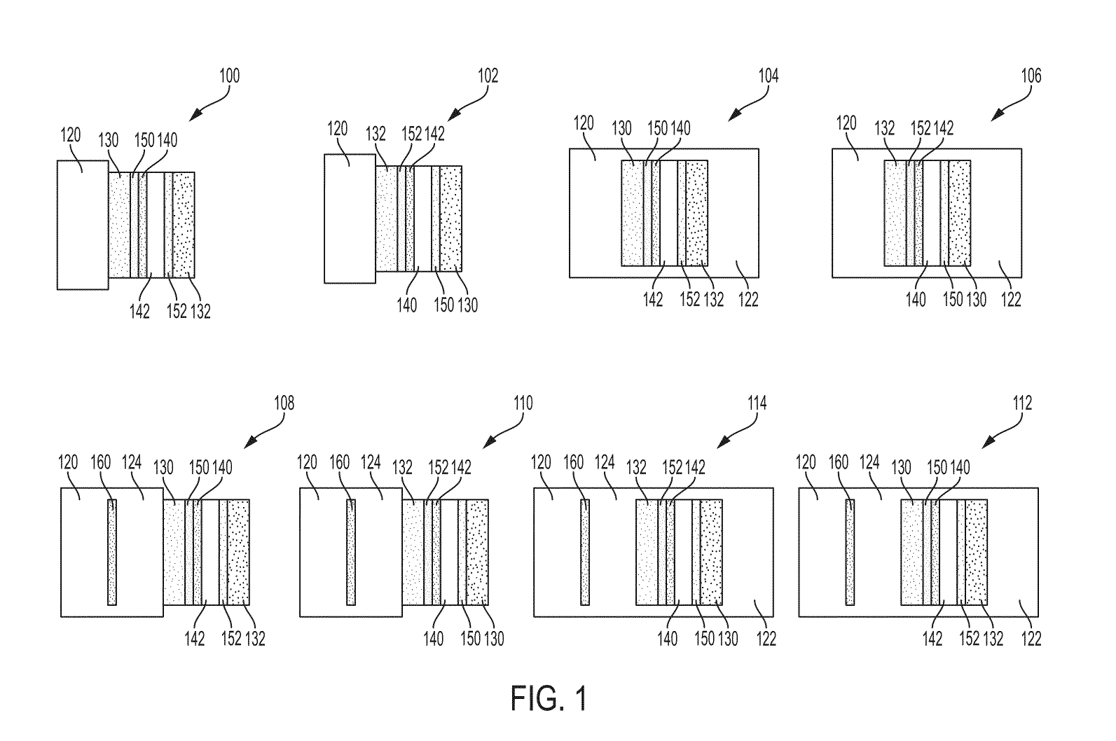

FIG. 1 shows exemplary configurations of optoelectronic devices. Device 100 includes a parylene substrate 120, an anode 130, an anode buffer layer 156, a donor 140, an acceptor 142, a cathode buffer layer 152, and a cathode 132. The anode 130, anode buffer layer 150, donor layer 140, acceptor layer 142, cathode buffer layer 152, and cathode 132 are active photovoltaic layers and can be collectively referred to as an active photovoltaic region. The active photovoltaic layers can be arranged in different configurations, an example of which is shown in device 102. Device 102 Includes components arranged in following order: a parylene substrate 120, a cathode 132, a cathode buffer layer 152, an acceptor 142, a donor 140, an anode buffer layer 150, and an anode 130. As configured, device 100 and device 102 can have overall device thicknesses of about 450 nm or less, depending on the selection of materials for each, component and the intended application of the optoelectronic device. In some embodiments, device 100 and device 102 can be configured without the anode buffer layer 150, without the cathode buffer layer 152, or without both the anode-buffer layer 150 and the cathode buffer layer 152, with overall device thicknesses that can be about 400 nm or less.

Ideal substrates for optoelectronic devices serve several functions: electrical buffer, mechanical support, optical element, and chemical barrier, while also being transparent in the operational wavelength range. Parylene is selected as the substrate material, having characteristics that provide these functions while having advantages over other substrate materials currently used today. Accordingly, parylene substrate 120 can be formed from one or more parylene variants including, for example, parylene C, parylene N, parylene D, and parylene among others. In some embodiments, parylene substrate 120 is formed from parylene C.

Parylenes are poly-para-xylylenes that are an industrially-relevant class of transparent insulating polymers. Variants of parylene differ functionally in their dielectric, mechanical, and chemical properties and differ chemically in their ring or aliphatic substitutions with various functional groups. Specific parylene variants can be selected to take advantage of their unique properties tailored for various applications.

Parylene C (poly-chloro-p-xylylene) is a singly-chlorinated variant that can form chemically resistant and low-permeability films with high, deposition rates, and accordingly is suitable for use as a substrate and encapsulant material. As used herein, the term “parylene” refers to parylene C, but it is understood that other parylene variants can be used within the scope of the invention. Parylene N is an unsubstituted poly-para-xylylene having the highest dielectric strength of the three variants, and a dielectric constant value independent of frequency. Parylene N can effectively penetrate crevices due to a high level of molecular activity that occurs during deposition. Parylene N is commonly used in high frequency applications due to its low dissipation factor and dielectric constant values. Parylene D is a dichloro-substituted poly-xylylene that provides thin films having greater thermal stability than parylene C and parylene N. Parylene HT® is a parylene variant that replaces the four alpha hydrogen atoms of the N-dimer with four fluorine atoms. Parylene HT® has high thermal and UV stability. Parylene HT® also has the lowest coefficient of friction and dielectric constant, and highest penetrating ability of the four variants.

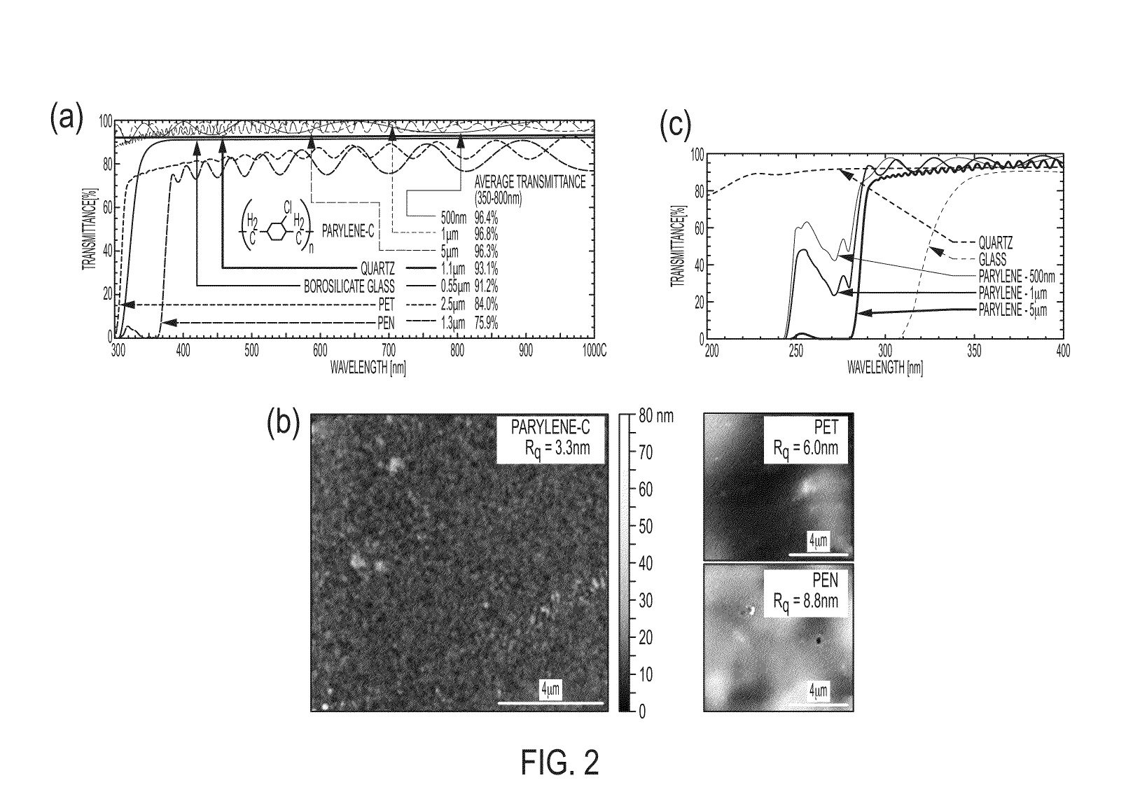

Parylene substrates exhibit a wide range of favorable properties including, for example, chemical resistance (due to, at least in part, high crystallinity and robust inter-domain linkages), relatively high melting point of about 290° C., low residual stress, high flexibility and heat moldability, comparatively high mechanical strength (Young's modulus of about 4 GPa), yield strength of about 55 MPa, low dielectric constant (about 3.1 at 1 kHz) and high optical transparency. FIG. 2 shows transparency and roughness of vapor-deposited parylene and alternative flexible substrates. FIGS. 2(a) and 2(c) show optical transmission spectra of parylene-C, PET, and PEN films with, varying thicknesses. Quartz and borosilicate glass are shown for reference. Parylene is optically transparent above 290 nm (see FIG. 2(c)), with an average transmittance from 350-800 nm of at least about 96% for film thicknesses of up to about 5 μm (see FIG. 2(a)). Parylene films are more transparent than PET and PEN films of similar thicknesses across visible and near-infrared wavelengths.

Parylene substrates can be formed onto a rigid- or semi-rigid carrier substrate. Suitable rigid or semi-rigid carrier substrate include, for example, glass, plastic, metal (e.g., Ag), paper or fabric. In preferred embodiments, parylene films can be deposited by the chemical vapor deposition. For example, parylene substrates can be prepared by pyrolytic polymerization (W. F. Gorham, A New, General Synthetic Method for the Preparation of Linear Poly-p-xylylenes, J. Polym. Sci. Part A-1 Polym. Chem. 4(12):3027-3039 (1966)). In particular, di-p-xylylene dimer in powder form can be sublimed at 90-150° C. and transported in the vapor phase into a pyrolysis furnace at about >600° C. Thermal cleavage of the dimer provides a highly reactive monomer species p-xylylene, which adsorbs and spontaneously polymerizes by chain growth on any surface in the deposition chamber kept below a critical condensation temperature of about 30° C. to about 130° C. (for example, at about 90° C. for parylene C). The resulting polymer is linear, polycrystalline with sub-micron domains, and of high, molecular weight (between about 200,000 to about 400,000 g/mol).

At thicknesses as low as about 30 nm, parylene substrates can exhibit smooth,

homogeneous, conformal, pinhole-free surfaces having a root mean square roughness (R_{q}) of less than 5 nm, for example, between about 2.5 nm to about 5 nm, and. between about 3 nm to about 3.5 nm. FIG. 2(b) shows atomic-force microscopy (AFM) images of parylene-C on glass, PET, and PEN. Parylene-C films exhibit very low surface roughness, particularly among thin polymer substrates. The root mean-squared .surface roughness (R_{q}) of parylene is about 3.3 nm, compared to 6.0 nm for PET and 8.8 nm for PEN.

Film thicknesses can be precisely controlled to allow the fabrication of arbitrarily thin substrates with thicknesses ranging from, nanometer-range to tens of microns with near-angstrom-level resolution at deposition rates of up to about 5 Å/s using, for example, a quartz crystal thickness monitor and gate valve. In comparison, currently available commercial systems provide film thicknesses of up to about 100 μm at rates of about 10 Å/s (about 17 min/μm) or higher. Parylene substrates can have thicknesses of about 100 nm to about 10 μm. In some embodiments, parylene substrates have thicknesses of about 5 μm or less, for example, between about 200 nm to about 5 μm, between about 200 nm to about 3 μm, between about 200 nm to about 1 μm, between about 250 nm to about 1 μm, and between about 250 nm to about 500 nm. Parylene substrates can be formed with precise control, having a thickness tolerance of less than about ±15 nm, for example, between about ±1 nm to about ±15 nm, between about ±1 nm to about ±10 nm, between about ±3 nm to about ±10 nm, between about ±5 nm to about ±10 nm, between about ±5 nm to about ±12 nm, and between about ±8 nm to about ±12 nm.

Monomer adsorption processes, i.e., impingement, physiosorption and chemisorptions (reaction with existing chain-end radicals), dictate surface concentrations and limit the deposition rate, which typically increases linearly with pressure and ranges between about <1 to about 5 μm per hour (with parylene on the high end). Ultra-thin parylene substrates, including parylene substrates having photovoltaic active layers disposed thereon, are flexible and strong, maintaining their structural integrity and does not partially or completely rip or tear when released (e.g., by peeling) from the carrier substrate. The carrier substrate can be reused after the device is released, allowing a feed-in roll typically used in conventional roll-to-roll processing to be eliminated from the process.

Parylene substrate formation by chemical vapor deposition can be advantageously utilized in bottom-up fabrication processes to form optoelectronic devices at ambient temperatures. In an exemplary bottom-up fabrication process, the substrate itself can be vapor-deposited onto a carrier substrate as part of the same process line as the functional optoelectronic device layers, for example, in high-throughput roll-to-roll processing. All fabrication steps, including substrate formation, active photovoltaic layer formation and encapsulation, layer formation, can be carried out in continuous succession in a fully contained, controlled environment, for example, under vacuum or under an inert atmosphere. This in situ processing can minimize contamination issues inherent in using separately manufactured substrates, which may negatively impact the performance of subsequently-deposited active layers. Parylene substrates are free of contaminants, such as dust particles, water and oxygen, and can serve as either a standalone substrate or a buffer layer for subsequent device processing. Unlike solution-deposited and cured substrate materials, such as polyimide, room-temperature vapor-deposited film does not require annealing or other post-deposition treatment to drive off residual solvents and reagents. Suitable inert atmosphere include, for example, an environment under nitrogen, noble gases (e.g., argon, neon, krypton, xenon, radon), and the like, or mixtures thereof. Suitable vacuum environments include moderate to high vacuum, for example, between about 10⁻³ Torr to about 10⁻² Torr, and even to about 10^{-≢}Torr to about 10⁻⁸ Torr.

Once parylene substrate 120 is formed, active photovoltaic layers (i.e., anode 130, anode buffer layer 150, donor 140, acceptor 142, cathode buffer layer 152, and cathode 132) can be formed over the parylene substrate 120 by any suitable vapor- or solution-phase method well-known in the art. Such films can be composed of conventional metals and semiconductors, nanostructured materials that can be processed at low temperatures, organic molecules, polymers, nanoparticles, and colloidal nanocrystals (quantum dots).

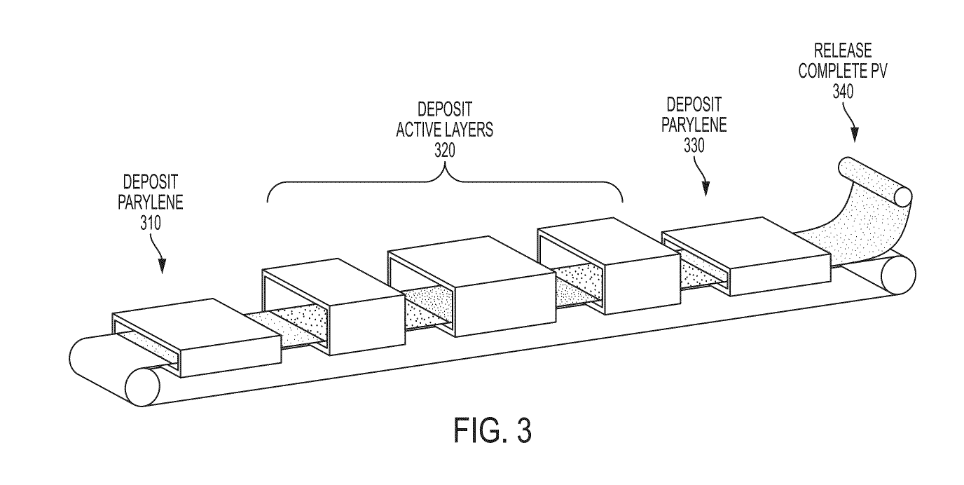

FIG. 3 shows an exemplary roll-to-roll manufacturing process for fully vapor-deposited thin-film solar cells on a parylene substrate. First, parylene can be deposited onto a carrier substrate surface on a roll-to-roll apparatus to form the substrate 310. Active photovoltaic materials can then be deposited by conventional vapor- and solution-based methods, including thermal evaporation, sputtering, and spin casting, to form active photovoltaic layers 320. An optional encapsulation layer can be formed by depositing parylene 330, and finally the completed device can be released from the carrier substrate 340, leaving the carrier substrate clean for reuse in the roll-to-roll process. In situ vapor-deposited parylene substrates do not require additional cleaning or mounting steps, simplifying the handling of extremely thin substrates.

In some embodiments, nanostructuring of parylene substrates can be used to modify optical properties. Parylene membranes can be physically molded on non-planar substrates, forming micro- and nano-textured surfaces by employing a 3-D patterned carrier rather than smooth, glass or silicon carriers. Such textured substrate can be engineered for light trapping in thin-film solar cells.

Due to the versatility of vapor deposition, parylene substrates and parylene

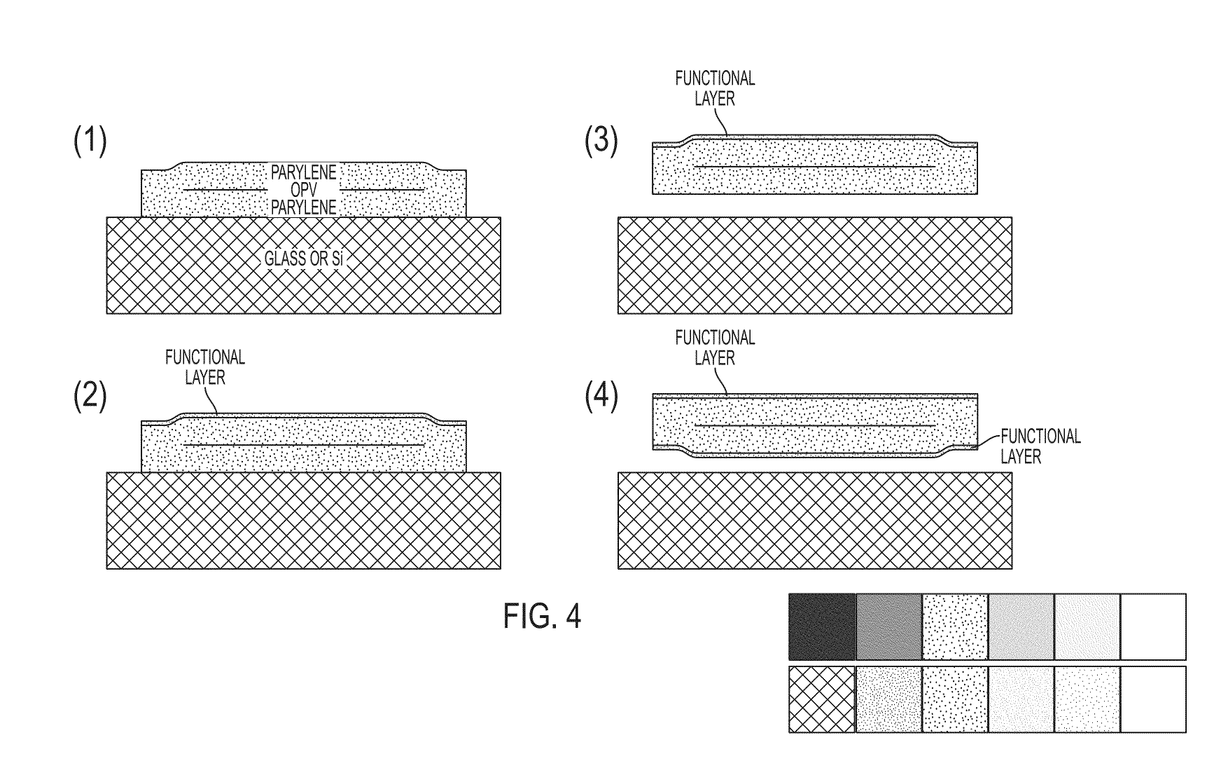

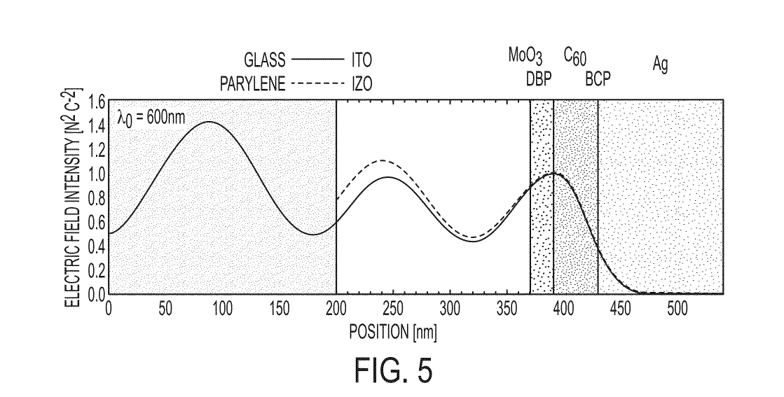

encapsulants can be enhanced by coating before or after release with UV-blocking films (e.g., CeO₂) and other functional films (e.g., optically active films (such as upconverting and downconverting films), moisture barriers, selectively absorptive films). FIG. 4 shows a process for enhancing parylene substrates with functional coatings. After fabrication of parylene-encapsulated devices and prior to release (1), functional films (e.g., UV-absorbing CeO₂ coatings) can be deposited by CVD or PVD (2). Devices can then be released from a earner substrate (3), and additional functional coatings can be applied on the reverse side (4). In other embodiments, functional materials (e.g., UV-blocking materials, optically active materials, moisture barrier materials, selectively absorptive materials) can also be doped directly into parylene itself during substrate formation (e.g., during CVD of parylene substrate layer). In other embodiments, optical interference and microcavity effects can be engineered to enhance device performance (e.g., to maximize absorption of light near the active junction of a thin-film solar cell) through native index contrast with active materials or incorporation of other thin films within a parylene film. FIG. 5 shows an example of an electric field intensity profile in organic solar cells based on glass/indium tin oxide (ITO) (dashed line) in comparison with parylene/indium zinc oxide (IZO) (solid line). The distribution for a free-space optical wavelength of 600 nm is shown. Optimization of microcavity effects can include, for example, integration of thin metallic layers in the parylene film to maximize field intensity near the tetraphenyldibenzoperiflanthene (DBP)/buckminsterfullerene (C₆₀) heterojunction. The field distribution can be modeled using a transfer-matrix approach.

Electrodes (i.e., anode 130 and cathode 132) are selected for key performance metrics, in particular optical transparency (e.g., having an average transmittance between about 350 nm to about 800 nm) and electrical resistivity (μΩ-cm) or sheet resistance (e.g., less than about 50 Ω/□, less than about 20 Ω/□ and less than about 10 Ω/□). Electrode material and their amounts are well-known, and can be readily selected by a person of ordinary skill in the art.

Anode 130 can be, for example, a transparent high work function hole-injecting conductor, such as an indium zinc oxide (IZO) layer. Other anode materials can include indium tin oxide (ITO) and fluorine-doped tin oxide (FTO). The anode can have a thickness of about 50 nm to about 500 nm or greater.

Cathode 132 can be, for example, a low work function (e.g., less than 4.0 eV), electron-injecting, metal, such as Al, Ca, a lithium-aluminum alloy (Li:Al), or a magnesium-silver alloy (Mg:Ag), a high work function metal (e.g., Au, Ag, Pt), a graphene electrode or a transparent conductor. The cathode can have a thickness of about 50 nm to about 500 nm or greater.

The donor layer 140 can have a thickness of about 5 nm to about 100 nm, about 10 nm to about 60 nm, and about 20 nm to about 40 nm. The acceptor layer 142 can have a thickness of about 5 nm to about 100 nm, about 10 ran to about 60 nm, and about 20 nm to about 40 nm.

Materials for the donor layer 140 and acceptor layer 142 can be selected according to desired energy levels and other material properties. The material of a donor layer, also known as P-type material, can be selected based on the material's ability to transport holes. The material of an acceptor layer, also known as N-type material, can be selected based on the material's ability to transport electrons. Suitable materials can have high efficiency light-to-electricity conversion and can be organic or inorganic. In some cases, a device can include an additional light absorbing material, such as, for example, semiconductor nanocrystals, organic dyes, as well as organic or inorganic semiconductors for electrical transport.

Materials for the donor layer 140 and acceptor layer 142 can be selected from common organic semiconducting compounds, for example, tetraphenyldibenzoperiflanthene (DBP), buckminsterfullerene (C₆₀), phthalocyanine-based donor compounds (e.g., chloroaluminum phthalocyanine (ClAlPc), phthalocyanine, phthalocyanine/bisnaphthohalocyanine), polyphenol, polyanthracene, polysilane, polypyrrole, 4,4′-bis[N-(1-naphthyl)-N-phenyl-amino]biphenyl (NPB), and N,N′-diphenyl-N,N′-bis(3-methylphenyl)-(l,r-biphenyl)-4,4′-diamine (TPD), B-NPB (N,N′-bis(naphthalen-2-yl)-N,N′-bis(phenyl)-benzidine), spiro-TPD (N,N-Bis(3-methylphenyl)-N,N′-bis-(phenyl)-9,9-spiro-bifluorene), spiro-NPB (N₅N′-bis(naphthalen-1-yl)-N,N′-bis(phenyl)-9,9-spiro-bifluorene), DMFL-TPD (N,N′-bis(3-methylphenyl)-N,N′-bis(phenyl)-9,9-dimethyl-fluorene), DMFL-NPD (N₅N′-bis(naphthalen-1-yl)-N,N′-bis(phenyl)-9,9-dimethyl-fluorene), DMFL-TPD (N,N′-Bis-(3-methylphenyl)-N,N′-bis(phenyl)-9,9-diphenyl-fluorene), DPFL-NPB (N₅N′-Bis(naphthalen-1-yl)-N,N′-bis(phenyl)-9,9-diphenyl-fluorene), spiro-TAD (2,2′,7,7′-tetrakis(N,N-diphenylamino)-9,9′-spirobifluorene), BPAPF (9,9-bis[4-(N,N-bis-biphenyl-4-yl-amino)phenyl]-9H-fluorene), NPAPF (9,9-Bis[4-(N,N-bis-naphthalen-2-yl-amino)phenyl]-9H-fluorene), NPBAPF (9,9-Bis[4-(N,N′-bis-naphthalen-2-yl-N,N′-bis-phenyl]-9H-fluorene), spiro-2-NPB (2,2′,7,7′-Tetrakis[N-naphthalenyl(phenyl)-amino]-9,9-spiro-bifluorene, PAPB (N,N′-bis(phenanthren-9-yl)-N,N′-bis(phenyl)-benzidine), spiro-5(2,7-Bis[N,N-bis(9,9)-spiro-bifluorene-2-yl)-amino]-9,9-spiro-bifluorene), spiro-bifluorene), spiro-DBP (2,2′-bis[N,N-bis(biphenyl-4-yl)amino]9,9-spiro-bifluorene, spiro-BPA (2,2′-Bis(N,N-di-phenyl-amino)9,9-spiro-bifluorene), CuPc (Phthalocyanine, Copper complex), m-MTDATA (4,4′4″-tris(N-3-methylphenyl-N-phenyl-amino)triphenylamine), 2T-NATA (4,4′4″-Tris(N-(2-naphthyl)-N-phenyl-amino)triphenylamine, IT-NATA (4,4′,4″-tris(N-1-naphthyl)-N-phenyl-amino)triphenylamine), NATA (4,4′,4″-tris(N,N-diphenyl-amino)triphenylamine), PPDN (pyrazino[2,3-f][1,10]phenanthroline-2,3-dicarbonitrile), MeO-TPD (N,N,N′N″-tetrakis(4-methoxy-phenyl)benzidine), MeO-spiro-TPD (2,7-bis[N,N-bis(4-methoxy-phenyl)amino]9,9-spiro-bifluorene), F4-TCNQ (tetrafluoro-tetracyanoquinodimethane), NTCDA (naphthalenetetracarboxylic dianhydride), TCNQ (tetracyanoquinodimethane), parylene-based compounds (e.g., PTCDA (3,4,9,10-perylenetetracarboxylic dianhydride)), BCP (bathocuproine), CBP (4,4′-bis(9-carbazolyl)-1,1′-biphenyl), F16-CuPc (Copper(II) 1,2,3,4,8,9,10,11,15,16,17,18,22,23,24,25-hexadecafluoro-29H,31H-phthalocyanine), PTCBI (3,4,9,10 perylenetetracarboxylic bisbenzimidazole), NPD (N,N′-diphenyl-N,N′-bis(1-naphthyl)-1-1′biphenyl-4,4″diamine), or pentacene.

Materials for the donor layer 140 and acceptor layer 142 can also be selected from common inorganic semiconducting materials, such as a metal oxide, a metal sulfide, a metal selenide, a metal telluride, a metal nitride, a metal phosphide, a metal arsenide, or metal arsenide. The metal oxide can be a mixed metal oxide, such as, for example, ITO, In a device, a layer of pare metal oxide (i.e., a metal oxide with a single substantially pure metal) can develop crystalline regions over time degrading the performance of the device. A mixed metal oxide can be less prone to forming such crystalline regions, providing longer device lifetimes than available with, pure metal oxides (e.g., binary or tertiary oxides, such as IZO or indium gallium zinc oxide). The metal oxide can be a doped metal oxide, where the doping is, for example, an oxygen deficiency, a halogen dopant, or a mixed metal. The inorganic semiconductor can include a dopant. In general, the dopant can be a p-type or an n-type dopant. Anode 140 (hole transport layer) can include a p-type dopant. Cathode 142 (electron transport layer) can include an n-type dopant.

Anode buffer layer 158 can have a thickness of less than 100 nm, for example, between about 5 nm to about 100 mm between about 10 nm to about 50 nm, between about 15 nm to about 40 nm and between about 20 nm to about 30 nm. Cathode buffer layer 152 can have a thickness of less than 100 nm, for example, between about 3 nm to about 100 nm, between about 5 nm to about 50 nm, between about 8 nm to about 30 nm and between about 8 nm to about 20 nm. Anode buffer layer 150 and cathode buffer layer 152 are interlayers that enhance device performance and efficiency. Suitable materials for anode buffer layer 150 and cathode buffer layer 152, and their amounts are well-known and can be readily selected by a person of ordinary skill in the art.

Suitable interlayer materials include, for example, low work function metals, metal oxides, organic molecules and self-assembled monolayers.

Low work function metals can be used in cathode buffer layer to reduce electrode work function for more efficient electron extraction and also can serve as a buffer layer to prevent cathode materials (e.g., Al, Ag) from penetrating into organic layers during thermal evaporation processes. Low work function metals include, tor example, alkali metals (e.g., Ca, Ba, Mg) and alkali metal compounds (e.g., Cs₂CO₃ and LiF).

Metal oxides can be electron-extracting or hole-extracting and their selection can be determined by considering the energy level of their conduction band and valence band as an electron or a hold extraction layer. Hole-extracting materials are suitable for anode buffer layer 150 and include, for example, MoO₃, V₂O₅, WO₃, and NiO. Electron-extracting materials are suitable for cathode buffer layer 152 and include, for example, TiOₓ and ZnO.

Organic interlayer molecules can be P-type hole-collecting/transporting materials or N-type electron-extracting/transporting materials. P-type materials are suitable for anode buffer layer 150 and include, for example, Poly(3,4-ethylenedioxythiophene) (PEDOT), poly(3,4-ethylenedioxythiophene) polystyrene sulfonate (PEDOT:PSS), sulfonated poly(diphenylamine), polyaniline (PANI) and polyaniline-poly(styrene-sulfonate) (PANI-PSS). N-type materials are suitable for cathode buffer layer 152 and Include, for example, bafhophenanthroline (BPhen) and bathocuproine (BCP).

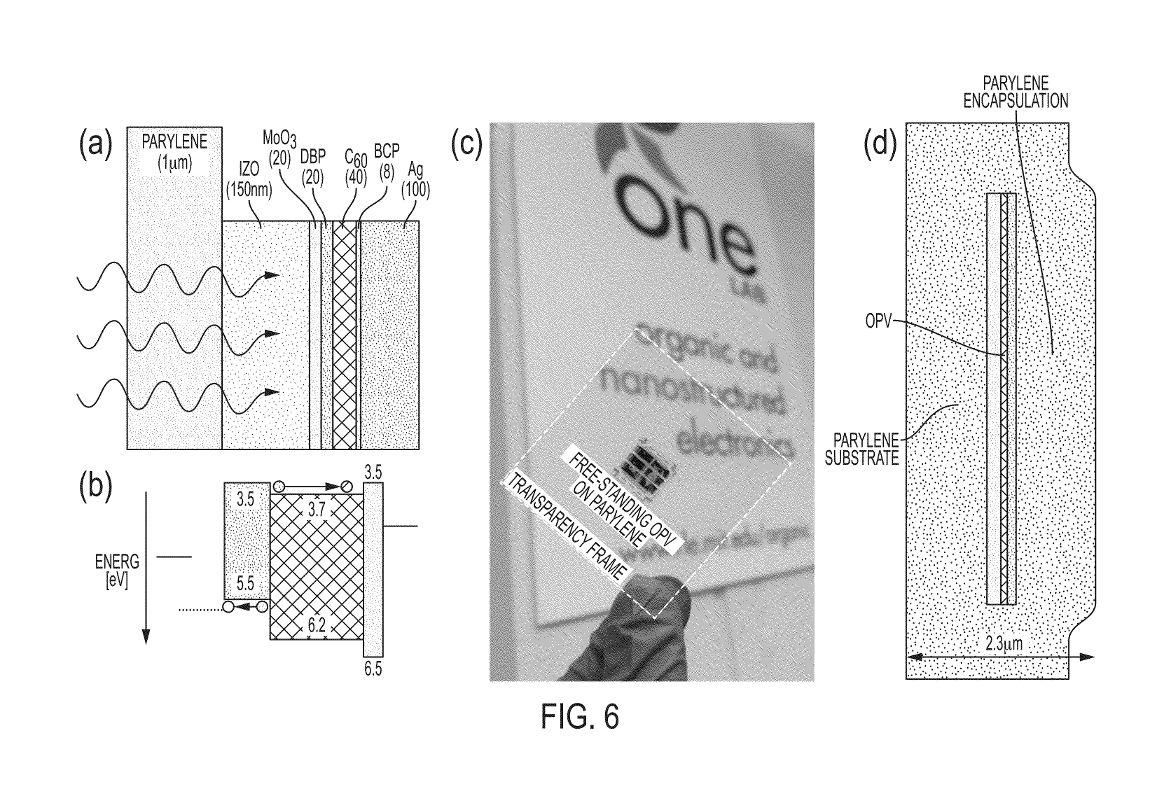

FIG. 6(a) shows an exemplary planar heterojunction optoelectronic device, on 1 μm thick parylene substrate and based on DBF and C₆₀ with thicknesses shown to scale. Light first passes through parylene substrate layer and into the active photovoltaic layers. The active photovoltaic layers include an IZO anode (about 150 nm thickness), a MoO₃ anode buffer layer (about 20 nm thickness), a DBP donor layer (about 20 nm thickness), a buckminsterfullerene. (C60) acceptor layer (about 40 nm thickness), a BCP cathode buffer layer (about 8 nm thickness) and a Ag cathode (about 100 nm) thickness. The total optoelectronic device thickness is less than 1.4 μm. FIG. 6(b) shows a nominal energy band diagram for a solar cell having a BCP donor, C₆₀ acceptor and BCP interface buffer (Fujishima et al., Organic thin-film solar cell employing a novel electron-donor material;” Sol. Energy Mater. Sol. Cells 2(109, 93(6-7), 1029-1032)). This solar cell exhibited an open-circuit voltage (V_{oc}) of about 0.92 V, a short-circuit current density (J_{sc}) of about 6.3 mA/cm² and a conversion efficiency of about 3.6% at about 100-mW/cm² simulated AM1.5G sunlight. The high V_{oc} and J_{sc} of the DBP-based cell is attributed to the DBF's highest occupied molecular orbital (HOMO) level about 5.5 eV and the effective light absorption, respectively. FIG. 6(c) shows pictures of a completed organic photovoltaic (OPV) device on parylene. This OPV device includes 6 active devices on the parylene substrate.

Optoelectronic devices can include modified substrates., hi particular, optically active layers can be embedded in the parylene substrate at precise locations for spectral manipulation and optical field optimization. For example, depositing one or more optically active layers (for example, upconverting or downconverting phosphors, e.g., rare-earth-doped ions and complexes (lanthanides and actinides), colloidal quantum dots and nanocrystals, and organic dyes, such as rhodamine, Lumogen-F®, Alq3, TPD) between substrate layers provides optically active laminates or substrates.

Examples of optoelectronic devices with modified substrates are shown in device 108 and device 119. Device 108 includes the components arranged in the following order: a first substrate 120, an optically active layer 160, a second substrate 124, an anode 130, an anode buffer layer 150, a donor 140, an acceptor 142, a cathode buffer layer 152, and a cathode 132, Active photovoltaic layers can be arranged in any order that provides a functional device, an example of which is shown in device 110. Device 110 includes components arranged in the following order, a first substrate 120, an optically active layer 160, a second substrate 124, a cathode 132, a cathode buffer layer 152, an acceptor 142, a donor 140, an anode buffer layer 150, and an anode 130. As configured, device 108 and device 110 can have overall device thicknesses of about 650 nm or less, depending on the selection of materials for each component and the intended application of the optoelectronic device. In some embodiments, device 100 and device 102 can be configured without the anode buffer layer 150, without the cathode buffer layer 152, or without both the anode buffer layer 150 and the cathode buffer layer 152, with overall device thicknesses that can be about 600 nm or less.

The first substrate layer 120 can be formed from parylene using methods described above for device 100. Optically active layer 160 can be deposited over first substrate layer 120 using well-known, vapor-phase techniques. The second substrate layer 124 can then be formed over optically active layer 160. The active photovoltaic layers can be formed over the second substrate layer as described above for device 100 and device 102. Second substrate layer 124 can be formed from parylene, but other suitable substrate materials can be used. Optically active layer 160 and second substrate layer 124 can be formed using well-known vapor phase techniques. First substrate layer 128 and second substrate layer 124 can each have thicknesses of about 100 nm to about 10 μm. In some embodiments, first substrate layer 120 and second substrate layer 124 each have thicknesses of about 5 μm or less, for example, between about 200 nm to about 5 μm, between about 200 nm to about 3 μm, between about 200 nm to about 1 μm, between about 250 nm to about 1 μm, and between about 250 nm to about 500 nm. First substrate layer 120 and second substrate layer 124 each can be formed with precise control, having a thickness tolerance of less than, about ±15 nm, for example, between about ±1 nm to about ±15 nm, between about ±5 nm to about ±15 nm, between about ±5 nm to about ±10 nm, and between about ±8 nm to about ±12 nm.

Optoelectronic devices can also include one or more encapsulation layers, examples of which, are shown in device 104 and device 106. Device 104 includes a substrate 120, an anode 130, an anode buffer layer 150, a donor 140, an acceptor 142, a cathode buffer layer 152, a cathode 132, and an encapsulation layer 122. Active photovoltaic layers can be arranged in any order that provides a functional device, an example of which is shown in device 106. Device 106 includes components in the following order: a substrate 120, a cathode 132, a cathode buffer layer 152, an acceptor 142, a donor 140, an anode buffer layer 150, an anode 130, and an encapsulation layer 122. As configured, device 104 and device 106 can have overall thicknesses of about 550 nm or less, depending on the selection of materials for each component and the intended application of the optoelectronic device. In some embodiments, device 104 and device 106 can be configured without anode buffer layer 150, without cathode buffer layer 152, or without both the anode buffer layer 150 and the cathode buffer layer 152, with overall device thicknesses that can be about 500 nm or less.

Optoelectronic devices with modified substrates can also include one or more encapsulation layers, examples of which are shown in device 112 and device 114. Device 112 includes the following components in order: a substrate 120, an optically active layer 160, a second substrate 124, an anode 130, an anode buffer layer 150, a donor 140, an acceptor 142, a cathode buffer layer 152, a cathode 132, and an encapsulation layer 122. Active photovoltaic layers can be arranged in any order that provides a functional device, an example of which is shown, in device 114. Device 114 includes the following components in order: a parylene substrate 120, an optically active layer 160, a second substrate 124, a cathode 132, a cathode buffer layer 152, an acceptor 142, a donor 140, an anode buffer layer 150, an anode 130, and an encapsulation layer 122. As configured, device 112 and device 114 can have overall thicknesses of about 750 nm or less, depending on the selection of materials for each component and the intended application of the optoelectronic device. In some embodiments, device 112 and device 114 can be configured without the anode buffer layer 150, without the cathode buffer layer 152, or without both the anode buffer layer 150 and the cathode buffer layer 152, with overall device thicknesses that can be about 700 nm or less.

Encapsulation layer 122 can have a thickness of about 10 nm to about 10 μm. In some embodiments, encapsulation layer 122 has a thickness of about 5 μm or less, for example, between about 100 nm to about 5 μm, between about 200 nm to about 3 μm, between about 200 nm to about 1 μm, between about 250 nm to about 1 μm, and between about 250 nm to about 500 nm. Encapsulation layer 122 can be formed with precise control, having a thickness tolerance of less than about ±15 nm, for example, between about ±1 nm to about ±15 nm, between about ±5 nm to about ±15 nm, between about ±5 nm to about ±10 nm, and between about ±8 nm to about ±12 nm.

FIG. 6(d) shows a cross-sectional view of a an exemplary, fully encapsulated OPV having a parylene substrate layer and a parylene encapsulation layer each with a thickness of about 1 μm and an encapsulated active photovoltaic region having about 300 nm thickness. Thicknesses are shown to scale.

Encapsulation layer 122 can be formed from any material such as suitable polymers and/or metal oxides, which exhibit high barrier performance to limit chemical (water vapor and oxygen penetration) degradation and mechanical degradation. Such barrier layers can be critical for devices with hygroscopic or easily-oxidized active materials. Suitable materials for encapsulation layer 122 are well-known and include, for example, inorganic oxides, organic polymers, silicone and the like. Organic polymers include, for example, parylene, PEN, PET, poly(1H,1H,2H,2H-perfluorodecylacrylate) (“PPFDA”), hexamethyldisiloxane (HMDSO), polyvinyl butyral (PVB), and ethylene vinyl acetate (EVA). Encapsulation layer 122 can be formed by any suitable vapor-phase method well-known in the art including, for example, thermal evaporation, sputtering, chemical vapor deposition or by lamination. In some embodiments, devices include more than one encapsulation layer. For example, multi-layered encapsulation films can include multiple layers of one or more materials, or alternating layers of two or more materials (e.g., alternating layers of parylene and aluminum oxide).

Parylene is a particularly suitable material, for encapsulation layers. Its low permeability to water and oxygen make it an effective barrier against oxygen and moisture, with a water vapor permeability about 5 times lower than PET, comparable to high-density polyethylene, and superior to common barrier films. Further, parylene as an encapsulation material for one device can serve as the substrate for another. The active regions of stacked devices can be directly overlaid or laterally displaced from one another, for example, an opaque solar cell can be placed laterally adjacent to a LED in a different layer and connected electrically. Direct stacking is make possible by photoactive materials with complementary absorption or emission, spectra, such that one device is transparent in the active wavelength range of another. In embodiments where devices include more than one encapsulation layer, the outer-most encapsulation layer is formed from parylene to allow for stacking of multiple devices that are each formed on a parylene substrate.

Optical coupling or isolation between devices can be tuned by incorporation of a selectively absorptive film between the parylene encapsulation of the bottom device and the parylene of the top device. While components are naturally electrically isolated from one another by the insulating parylene film, through-vias (e.g., by etching or masked deposition) can produce 3-D interconnections between stacked devices.

Its flexibility and mechanical robustness at such low thicknesses allow free-standing parylene thin films to be released without solvents. Advantageously, large-area (up to about 100 mm diameter) free-standing parylene films as thin as about 250 nm can be peeled off of silicon glass wafers as a single continuous sheet without any tearing. The solvent-free thin-film release technique is a key enabler for the bottom-up optoelectronic devices herein. A rigid or semi-rigid carrier is often used to facilitate handling of thin or flexible films during device processing. However, thin films are often fragile and may adhere strongly to the carrier surface. To release these membranes, soluble firms, such as photoresists, can be deposited between the carrier and the membrane and dissolved after fabrication is complete. Solvent-mediated release is a useful technique for fabricating devices, comprised of single- and multi-layer composite films. When using solvent-based processes, however, composite films must contain only solvent-insensitive materials. This requirement precludes the use of most organic semiconductors, which are of interest for optoelectronic applications, such as lasers, LEDs, and photovoltaics. In contrast the room-temperature, solvent-free parylene based membrane release methods described herein allows the integration of both solvent- and temperature-sensitive materials into multi-layer composite films for ultra-thin and lightweight optoelectronics.

While the principles of the disclosure have been Illustrated in relation to the exemplary embodiment shown herein, the principles of the disclosure are not limited thereto and include any modification, variation or permutation thereof.

### EXAMPLES

### Example 1

### General Fabrication of Optoelectronic Devices on Parylene Substrates

Fabrication of optoelectronic devices on a parylene substrate includes several key steps. First, a rigid or semi-rigid carrier substrate (e.g., glass, silicon, polyimide, silver) is cleaned and optionally treated with a release agent (for example, a surfactant, such, as 1% aqueous solution of Micro-90 detergent), to allow easier release of the completed optoelectronic device after fabrication. A base layer of parylene with a thickness of about 200 nm to about 1 μm is deposited by CVD onto a carrier, forming a parylene substrate. Active photovoltaic layers (e.g., metal, oxide, organic and nanoparticulate layers) is sequentially deposited and patterned on top of the parylene substrate. Deposition of a second parylene film allows for in-situ device encapsulation. Stack composition and structure, i.e., materials, layer thicknesses, geometries, can be varied and depend on the application. The completed multi-layer film is attached to a flexible cutout handle frame and released from the carrier by peeling. This continuous sheet is then transferred to another substrate or remains free-standing.

### Example 2

### Vapor-Depositing Solar Cells on Parylene

Materials and conditions: Parylene-C dimer (diX-C) was purchased from Uniglobe Kisco. An indium zinc oxide (In₂O₃ with 10 wt. % ZnO) sputter target (99.99% purity) was purchased from Idemitsu Corp. MoO₃ (Alfa Aesar, 99.9995%), tetraphenyldibenzoperiflanthene (DBP) (Lumtec, >99%), bathocuproine (BCP) (Lumtec, >99%), and Ag (Alfa Aesar, 99.999%) were used as received. C₆₀ (99.9%, Sigma-Aldrich) was purified once by thermal gradient sublimation. Solar cell fabrication was performed entirely at room temperature and under vacuum. Substrate transfer, shadow mask exchange, and all deposition steps from substrate to active photovoltaic layers was carried out without exiting base vacuum (10⁶ Torr), guaranteeing an ultra-clean processing environment.

Parylene substrate formation: Parylene-C films of varying thickness were deposited on glass and on complete OPV devices in a custom chamber. Glass and silicon substrates were cleaned by sonication in detergent, deionized water, and acetone (about 5 minutes each), followed by boiling in isopropanol twice for about 5 minutes and O₂ plasma treatment for about 1 minute. Prior to parylene deposition, 1% Micro-90 in deionized water was spin-coated on glass at about 2000 RPM (about 2000 RPM/s acceleration) for about 60 seconds to form a release layer. Parylene deposition was carried out. at a base pressure of about 5 mTorr. diX-C dimer was sublimed at about 90-120° C. and cleaved in a pyrolysis furnace at about 750° C. Deposition rates of about 0.1-3 Å/s were monitored with a quartz crystal microbalance.

Device fabrication: Small-molecule organic, solar cells were fabricated, by standard vapor-phase methods. Indium zinc oxide (about 150 nm) was deposited by RF-magnetron sputtering at a rate of about 0.4-0.8 Å/s, Ar pressure of about 6 mTorr, and RF power of about 50-80 W. MoO₃ (about 20-40 nm), DBF (about 20 nm), C₆₀ (about 40 nm), BCP (about 8 nm), and Ag (about 100 nm) were thermally evaporated at about 1 Å/s, with a base pressure of about 10⁻⁶ Torr. The active area of about 5.44 mm² was determined by the overlap of the IZO and Ag electrodes.

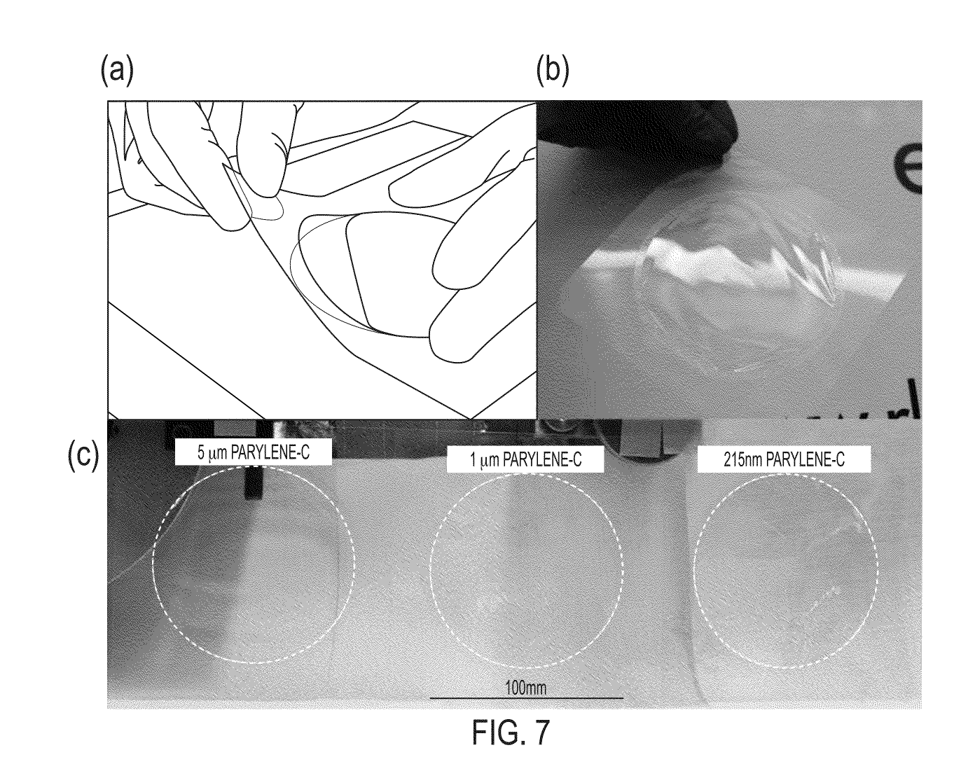

Parylene films and complete devices were released from the glass carrier by solvent-free, room-temperature delamination. Thick parylene films can be released easily from untreated silicon or glass, but release of thinner films often employs sacrificial release layers, such as the soluble films used for parylene-based electronics. Here, glass carriers were coated with dilute Micro-90 to reduce adhesion and facilitate subsequent dry release. Common thermally evaporated organic films (tris(8-hydroxyquinoline) aluminum (Alq3) and N,N′-bis(3-methylphenyl)-N,N′-diphenylbenzidine (TPD)) were investigated as release layers with and without annealing, but parylene adhesion to organic-coated glass was stronger than to detergent-treated carrier substrates. Plastic frames were cut from standard transparency sheets and adhered with double-sided adhesive to peel off and handle ultra-thin parylene membranes. The membranes were attached to the handle frames only at the perimeter, leaving the rest of the film free-standing. With this method, sub-micron-thick parylene films of up to about 100 mm diameter were released and showed no limit on releasable film area. FIG. 7 shows photos of various parylene-C thin films at various thicknesses that are released from glass carrier wafers. FIG. 7(a) shows parylene-C membranes are released from glass carrier wafers by dry delamination. FIG. 7(b) shows an approximately 5 μm thick transparent parylene-C membrane released from a 100 mm-diameter glass wafer and attached at perimeter to a cutout transparency film frame. FIG. 7(c) shows released 100 mm-diameter parylene films with thicknesses of about 5 μm, about 1 μm, and about 215 nm (left to right).

### Example 3

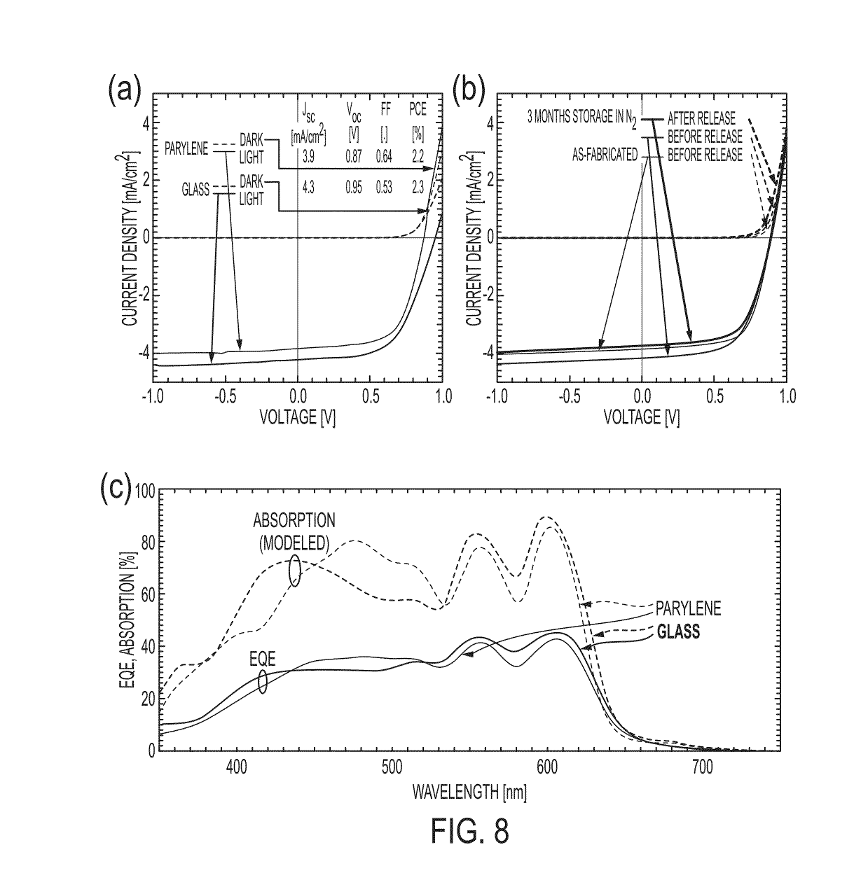

Performance comparison of small-molecule organic solar cells on parylene-C and on glass substrates. Organic solar cells fabricated on parylene membranes achieved power conversion efficiencies comparable to control devices on glass substrates. FIG. 8 shows a performance comparison, of small-molecule organic solar ceils on parylene-C and on glass substrates. FIG. 8(a) shows representative current density-voltage (J-V) characteristics in dark, and under AM1.5G illumination. Parylene- and glass-based devices exhibit similar performance, with average short-circuit current densities of about 3.9 mA/cm² and about 43 mA/cm², open-circuit voltages of about 0.87 V and about 0.95 V, fill factors of about 0.64 and about 0.58, and power conversion, efficiencies of about 2.2% and about 2.3%, respectively. The total, mass per area of about 3.6 g/m² for parylene-based devices results in a specific power of about 6.2 W/g. FIG. 8(b) shows the effect of storage time and parylene release on PV performance Parylene-based devices, were tested in N₂ atmosphere immediately after fabrication (prior to release from the glass carrier), then transferred to air, released, and laminated onto glass for further testing. The about 10% reduction in current density after release can be attributed to increased reflection loss due to wrinkling of parylene films during the release process, which persists upon lamination. Device performance was unaffected by the short-term (about 30 minutes) air exposure and mechanical strain encountered during release. Devices tested after about 3 months of storage in inert N₂ environment showed minimal degradation. FIG. 8(c) shows the external quantum efficiency (EQE) and modeled active-layer absorption spectra. The fraction of incident power absorbed in DBP and C₆₀ is calculated with a transfer-matrix model (Pettersson el al., “Modeling photocurrent action spectra of photovoltaic devices based on organic thin films,” J. Appl. Phys. 1999, 86(1), 487; Peumans et al., “Small molecular weight organic thin-film photodetectors and solar cells,” J. Appl. Phys. 2003, 93(7), 3693)). The modeled absorption in the active layers (DBP and C₆₀) explain minor differences in the EQE spectra of devices on parylene and on glass.

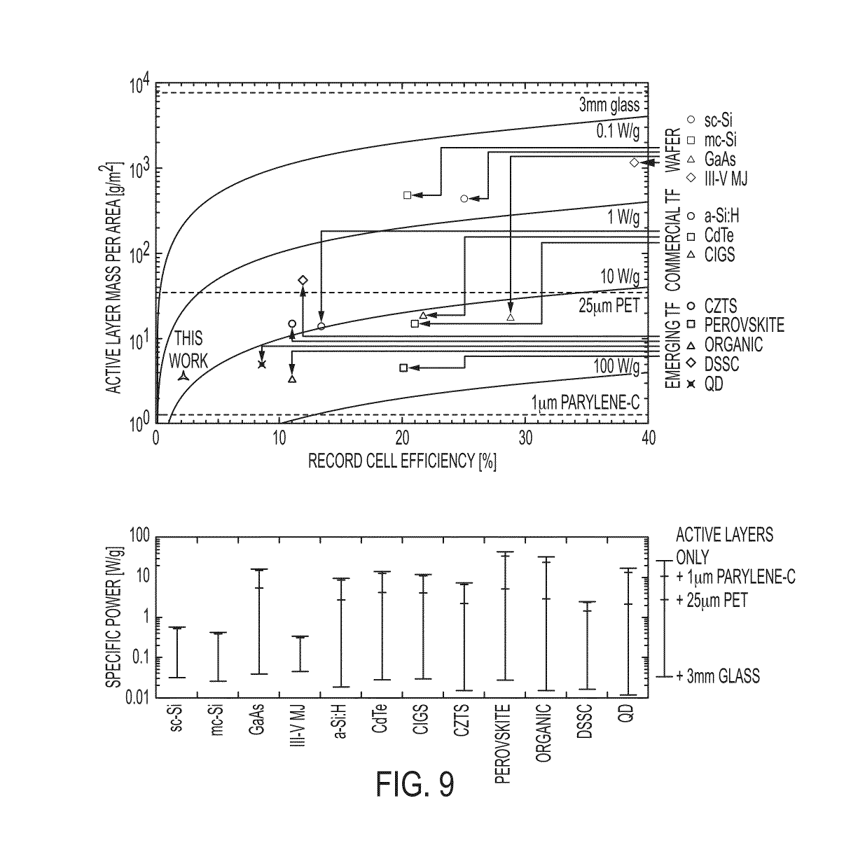

FIG. 9 shows the effect of substrate and active layers (including electrodes) on power-to-weight performance of current PV technologies. Mass per area vs. record cell efficiency (Best Research-Cell Efficiencies (rev. 11-13-201.4). National Renewable Energy Laboratory, 2014) are shown for active layers alone (top). Dashed lines represent substrates: about 3 mm-thick glass, about 25 μm polyethylene terepthalate (PET), and about 1 μm parylene-C. Typical thick glass and plastic substrates dominate the weight of thin-film (TF) cells. Specific power contours show that reducing cell and substrate weight per area is more effective than increasing efficiency when seeking high power-to-weight ratios. Emerging TF technologies are about 2-3× less efficient, but use about 10-100× less active material per unit area than deployed technologies. The three-point, marker labeled “This work” represents the cells (including parylene substrates) demonstrated. Specific power for active layers alone and with various substrate (or encapsulation) choices are shown in the bottom plot. Even at today's efficiencies, emerging TF technologies can reach higher specific power than commercial technologies by employing lightweight substrates. Wafer-based PV technologies include single-crystalline silicon (sc-Si), multicrystalline silicon (mc-Si), gallium arsenide (GaAs), and III-V multijunctions (III-V MJ). Commercial TF technologies, include hydrogenated amorphous silicon (a-Si:H). cadmium telluride (CdTe), and copper Indium gallium diselenide (CIGS). Emerging TF technologies include copper zinc tin sulfide (CZTS), perovskite PV, organic PV, dye-sensitized solar cells (DSSC), and colloidal quantum dot (QD) PV.

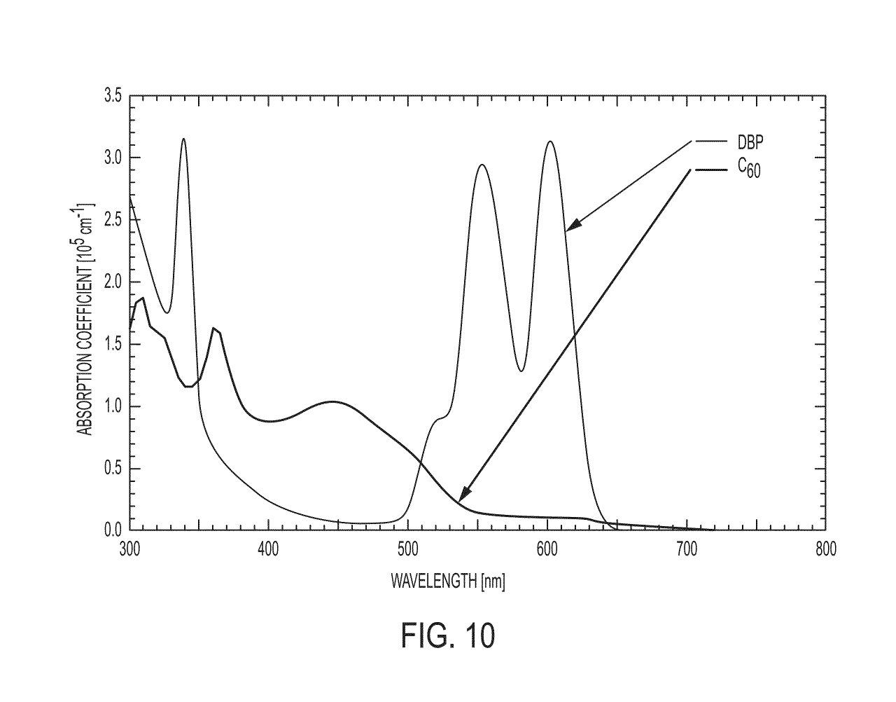

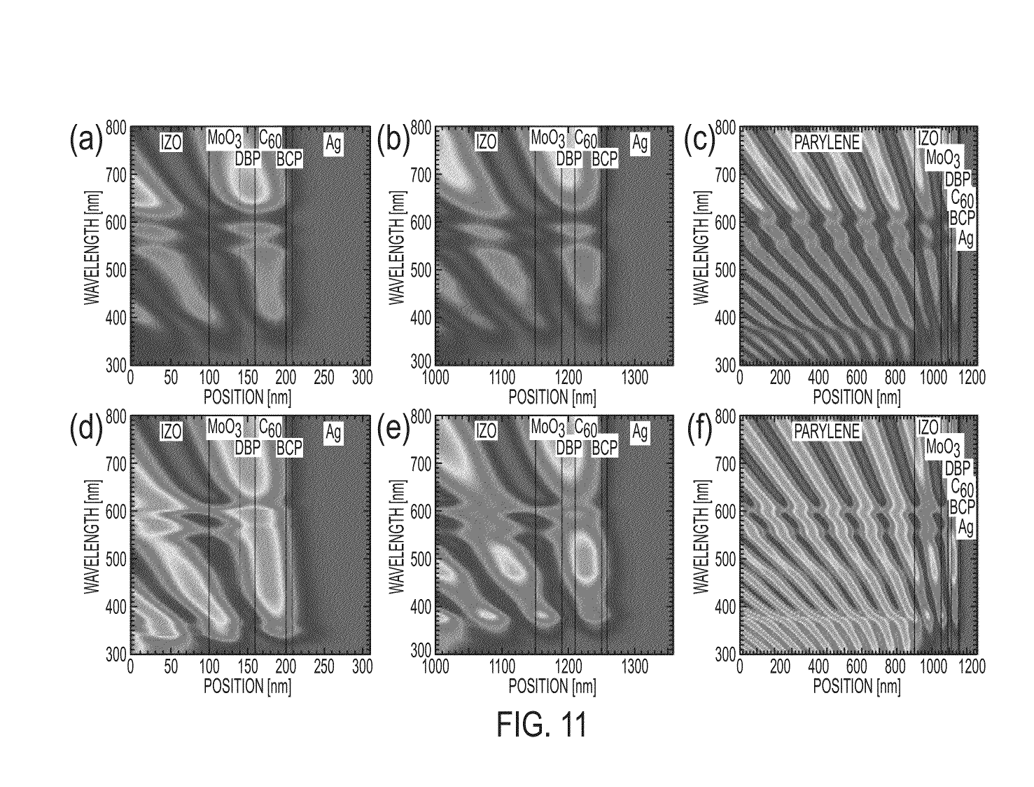

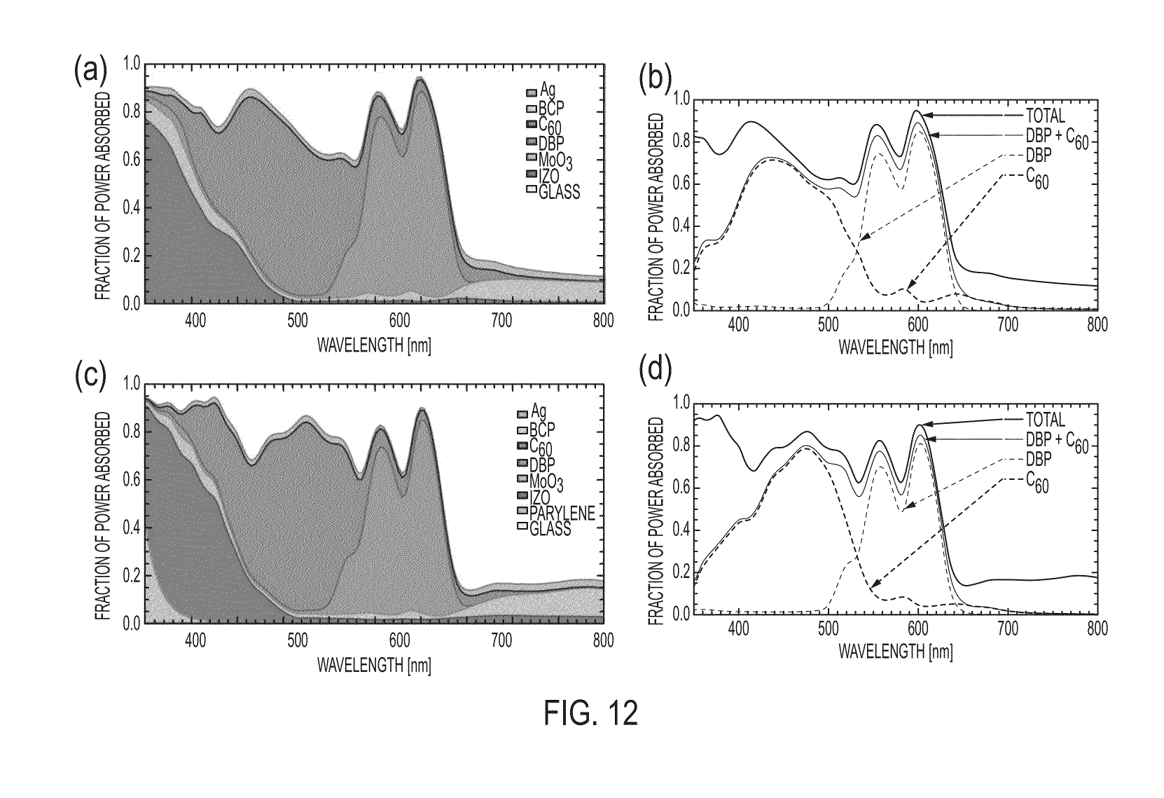

FIGS. 10-12 shows modeled field intensity profiles and absorption spectra. FIG. 10 shows the power absorption coefficient for active layers (DBF and C₆₀). Extinction coefficient spectra were derived from SE. FIG. 11 shows modeled electric field intensity map in OPV on glass and on parylene. Upper figures (FIGS. (a)-(c)) show un-normalized field intensity for OPV on glass (a) and on parylene (b, c). Different IZO thicknesses are employed for glass-based and parylene-based devices (about 100 nm and about 150 nm, respectively). Lower figures (FIGS. (d)-(f)) show the corresponding field intensity maps normalized to the maximum value at each wavelength to highlight the shift in location of the peak intensity with wavelength. Field profiles are calculated using a transfer-matrix optical model, with optical constants derived from SE. FIG. 12 shows modeled light absorption by layer in OPV on glass and on parylene. FIGS. 12(a) and 12b show absorption of OPV on glass with the following device structure: IZO (about 100 nm)/MoO₃ (about 40 nm)/DBF (about 20 nm)/C₆₀ (about 40 nm)/BCP (about 8 nm)/Ag (about 100 nm). FIGS. 12(c) and 12(d) show absorption of OPV on parylene with the following device structure: Parylene-C (about 1 μm)/IZO (about 150 nm)/MoO₃ (about 40 nm)/DBP (about 20 nm)/C₆₀ (about 40 nm)/BCP (about 8 nm)/Ag (about 100 nm). Absorption spectra are calculated using a transfer-matrix optical model with optical constants derived from SE.

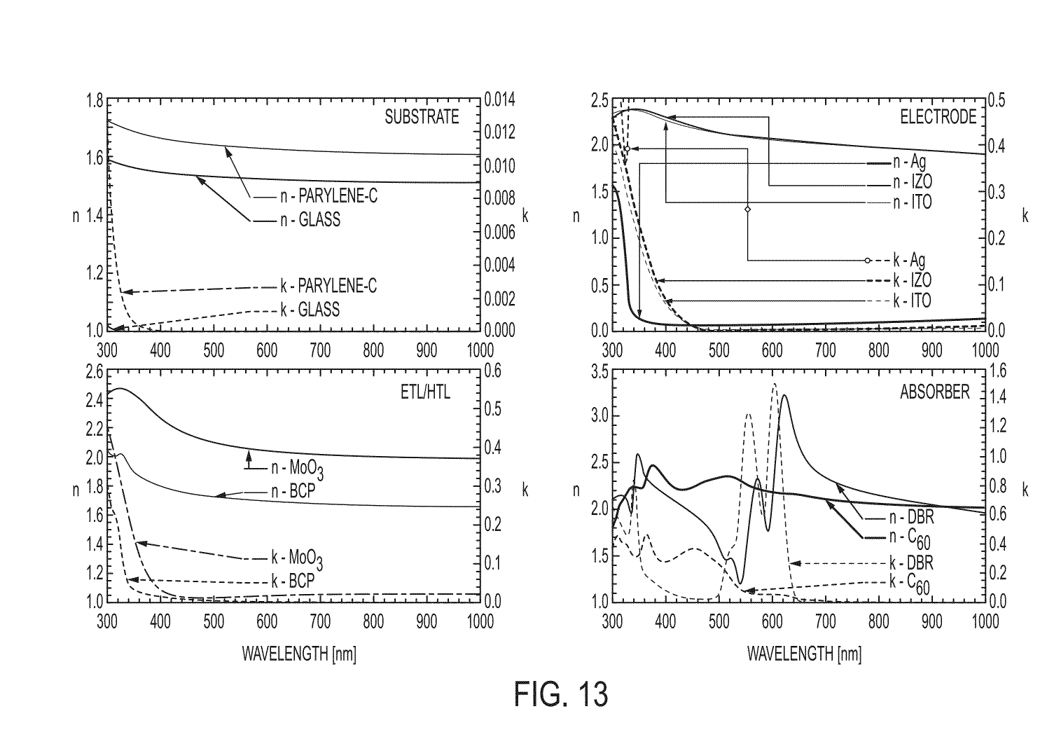

Integration of EQE weighted by the AM1.5G solar photon flux predicts short-circuit current densities of about 5.4 mA/cm² and about 5.6 mA/cm² for parylene and glass-based devices, respectively. The about 30-40% discrepancy with measured J_{SC} values may indicate underestimation of OPV performance due to spectral mismatch. FIG. 13 shows retractive indices (n) and extinction coefficients (k) of OPV materials: substrates (glass and parylene), electrodes (ITO, IZO, and Ag), buffer layers (BCP and MoO₃, respectively), and absorber layers (DBP, C₆₀). Optical constants were derived by fitting variable-angle spectroscopic ellipsometry (SE) data, in some cases simultaneously with UV-Vis transmittance data. To avoid oxidation and moisture-related degradation of organic films, a N₂-filled atmospheric cell was used for SE measurements for MoO₃, DBP, C₆₀, and BCP.

What is claimed is:

1. A photovoltaic device comprising:
a substrate layer comprising parylene, wherein the substrate layer has a thickness of between about 100 nm to about 10 μm and a thickness tolerance of about ±10 nm; and
one or more active photovoltaic layers disposed over the substrate layer, wherein the
one or more active photovoltaic layers comprises an anode layer, a donor layer, an acceptor layer, and a cathode layer.

2. The photovoltaic device of claim 1, wherein the one or more active photovoltaic layers further comprises first interlayer disposed between the anode layer and the donor layer; and second interlayer disposed between the acceptor layer and the cathode layer.

3. The photovoltaic device of claim 1, further comprising an encapsulation layer disposed over the one or more active photovoltaic layers.

4. The photovoltaic device of claim 1 having a weight-specific power of at least about 1 W/g.

5. The photovoltaic device of claim 1 having a weight-specific power in the range of about 1 W to about 1.0 W/g

6. The photovoltaic device of claim 1, wherein the total thickness of the photovoltaic device is less than about 1.5 nm.

7. The photovoltaic device of claim 1, wherein the total thickness of the photovoltaic device is in the range of about 400 nm to about 1.5 μm.

8. A method to form a multilayer photovoltaic device, comprising;
depositing a first parylene over one of a rigid- or a semi-rigid carrier surface to form a substrate layer, wherein the substrate layer has of thickness of between about 100 nm to about 10 μm and a thickness tolerance of about ±10 nm;
forming one or more active photovoltaic layers over the substrate layer; and
separating the substrate layer from the rigid or the semi-rigid carrier surface.

9. The method of claim 8, wherein the step of depositing the first parylene farther comprises vapor depositing parylene.

10. The method, of claim 8, wherein the step of depositing the first parylene further comprises forming a substrate layer having a thickness of between about 250 nm to about 5 μm and a thickness tolerance of about ±10 μm.

11. The method of claim 8, further comprising depositing a secondary parylene layer over the one or more active photovoltaic, layers to form an encapsulation layer.

12. The method of claim 8, further comprising performing all steps in continuous succession in a contained, controlled environment.

13. The method of claim 12, further comprising performing all steps under continuous vacuum or in an inert atmosphere.

14. The method of claim 8, further comprising separating the substrate layer from the rigid or semi rigid carrier surface, wherein the multilayer photovoltaic device is fully intact after separation.

15. The method of claim 8, wherein the substrate layer has a surface roughness in a range of about 3 nm to about 5 nm.

16. The method of claim 8, wherein forming the active photovoltaic layers further comprises:
forming an anode layer over the substrate layer;
forming a donor layer over the anode layer:
forming an acceptor layer over the donor layer; and
forming a cathode layer over the acceptor layer.

17. The method of claim 16, further comprising:
forming a first interlayer between the anode layer and the donor layer; and
forming a second interlayer between the acceptor layer and the cathode layer.

18. The method of claim 17, wherein forming the active photovoltaic layers further comprises:
forming a cathode layer over the substrate layer:
forming an acceptor layer over the cathode layer;
forming a donor layer over the acceptor layer; and
forming an anode layer over the donor layer.

19. The method of claim 18, further comprising:
forming a first interlayer between the anode layer and the donor layer; and
forming a second interlayer between the acceptor layer and the cathode layer.

20. The method of claim 8, wherein the total thickness of the photovoltaic device is less than about 1.5 μm.
